(19) United States
(12) Patent Application Publication
(10) Pub. No.: US 2009/0217967 A1
(43) Pub. Date: Sep. 3, 2009

(54) POROUS SILICON QUANTUM DOT PHOTODETECTOR

(75) Inventors: Harold J. Hovel, Katonah, NY (US); Joel P. de Souza, Putnam Valley, NY (US); Devendra K. Sadana, Pleasantville, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/039,826

(22) Filed: Feb. 29, 2008

(51) Int. Cl. H01L 31/042; H01L 31/00; H01L 21/02

(52) U.S. Cl. 136/249; 136/256; 438/73; 438/84; 257/E31.001; 257/E31.125; 257/E21.002

(57) ABSTRACT

Embodiments of the present invention provide a solar energy converter, which includes a silicon layer having at least two regions of a first and a second conductivity type that form a P-N junction, at least a portion of the silicon layer being porous, and pores in the portion of porous silicon containing a semiconductor material, the semiconductor material being different from silicon; and a first and a second electrode being placed at a bottom and a top surface of the silicon layer respectively. Methods of manufacturing the same are also provided.

### FIELD OF THE INVENTION

The present invention relates generally to the field of energy converters, particularly to solar energy converters. More specifically, the present invention relates to a porous silicon quantum dot photo-detector.

### BACKGROUND OF THE INVENTION

It is well known in the art that solar energy converters, also known as solar cells, may be made of a range of materials and have different structures. For example, one of the most commonly used structures of a solar cell may be a piece of solid semiconductor, such as silicon (Si), that contains a junction formed by a p-type doped region and an n-type doped region. The semiconductor is provided with electrodes, such as metal electrical contacts or contacting means, and may be coated with anti-reflection coatings on the surface that reduces reflection of light incident on the surface of the solar cell.

Silicon of porous type has also been used in making solar cells. A solar cell made of porous silicon generally includes an upper silicon region that is chemically treated such that a high number of pores are created below the surface, up to a pre-determined depth into the silicon region, with size of pores being controlled by the pore creation process. Porous Si has been used as part of an anti-reflection means for otherwise conventional Si solar cells, and has been made a part of the doped junction, that is, the heavily doped active “emitter” region of the solar cell.

Porous silicon regions have also been observed to emit light in a visible wavelength region when being suitably biased. This is because when dimensions of Si regions between pores are made in a range, commonly known as a quantum range of approximately 10 nm or less, the “band structure” of Si material is altered from that of a normal bulky Si material to that of a quantum range. When being applied a bias voltage, electric field resulting from the bias voltage causes the electroluminescence of the quantum range Si material.

Another type of solar energy converter or solar cell may include the use of particles of a semiconductor material such as TiO₂ or ZnO that are coated with a dye and encased in an electrolyte. In this solar cell, known as an electrochemical type solar cell, the dye absorbs an incident light, creates hole-electron pairs, and transfers the created electrons to the TiO₂ or ZnO for transmission to an electrode. The electrolyte may contain a redox chemical that absorbs the holes and combines them with electrons from an opposite electrode to complete a closed circuit.

Quantum dots are proposed to replace dye coating generally applied on TiO₂ (or ZnO) in an electrochemical type solar cell. As is known in the art, the term quantum dot here refers generally to materials, such as semiconductor or metal, in a quantum range dimension of approximately 10 nm or less. In addition, quantum dots are suggested for being incorporated in solid solar cells made of III-V semiconductor compounds in a junction depletion region, as quantum wells are generally used, all of which may help enhance solar cell performance by increasing absorption of light that would otherwise be lost.

Enhancements to solar cell performance using quantum dots have been described in a variety of materials. For example, Ruangdet et al. described enhancements in GaAs photo-detectors using vapor-grown InAs quantum dots in the Conference Record of the Photovoltaic Specialists Conference, 2006, page 225. Alguno et al. described silicon solar cells containing Ge quantum dots by vapor growth of alternate stacked silicon and Ge layers in Applied Physics Letters Vol. 83, page 1258 (2003), and Electrochemical Society Proceedings Vol. 2004-07, page 1067.

Electrochemical solar cells incorporating TiO₂ coated with light-absorbing dye encased in a redox-containing electrolyte have been described, for example, by Duffy et al., in Electrochemical Society Proceedings Vol. 2001-10, page 85. Electrochemical cells incorporating quantum dots have been described in Liu et al., Journal of Physical Chemistry Vol. 97, page 10769 (1993), and in Hoyer et al, Applied Physics Letters Vol. 66, page 349 (1995).

### SUMMARY OF EMBODIMENTS OF THE INVENTION

Embodiments of the present invention provide an energy converter, which includes a silicon layer having at least two regions of a first and a second conductivity type that form a P-N junction, at least a portion of the silicon layer being porous, and pores in the portion of porous silicon containing a semiconductor material, the semiconductor material being different from silicon; and a first and a second electrode being placed at a bottom and a top surface of the silicon layer respectively.

According to one embodiment, the semiconductor material includes quantum dots, the quantum dots having a size less than 10 nm, between about 1 nm and about 7 nm, and preferably between about 2 nm and about 5 nm, and being dispersed in the pores.

In one embodiment, the semiconductor material has a band-gap smaller than that of silicon, and is selected from a group consisting of InAs, InSb, GaSb, PbS, PbSe, PbTe, Ge, and GaInAs. In another embodiment, at least one of the first and second electrodes is a metal grid or a transparent conducting oxide of tin oxide (SnO), zinc oxide (ZnO) or indium oxide (InO). In yet another embodiment, the silicon layer is a thin-film of silicon or a bulk silicon wafer being formed on top of a substrate and the substrate is selected from a group consisting of glass, ceramic, plastic, metal, and semiconductor.

According to another embodiment, the pores in the portion of porous silicon have a size less than 10 nm, and are substantially filled with the semiconductor material, which is in substantially intimate contact with walls of the pores. In one embodiment, the pores are quantum volume having a size between about 1 nm and about 7 nm, and preferably between about 2 nm and about 5 nm. In another embodiment, the first conductivity type silicon is a p-doped type silicon and the second conductivity type silicon is an n-doped type silicon.

According to yet another embodiment, the semiconductor material has a band-gap larger than that of silicon, and is selected from a group consisting of CdSe, CdS, CdTe, ZnSe, ZnTe, ZnS, GaN, InN, GaAs, GaP, and InP.

Embodiments of the present invention also provide a method of manufacturing an energy converter. The method includes forming a layer of silicon on a substrate having a first electrode thereupon, said layer of silicon having a first and a second conductivity type, said first and second conductivity types forming a P-N junction; creating pores in at least a portion of said layer of silicon, thus forming a porous silicon region of said layer of silicon; filling said pores in said porous silicon region with a semiconductor material different from silicon; and forming a second electrode on top of said layer of silicon.

### BRIEF DESCRIPTION OF THE DRAWINGS

The present invention will be understood and appreciated more fully from the following detailed description of the invention, taken in conjunction with the accompanying drawings of which:

FIG. 1 is a demonstrative illustration of a simplified structure of a solar cell in accordance with one embodiment of the present invention;

FIG. 2 is a simplified flowchart illustration of a method of forming the solar cell illustrated in FIG. 1 in accordance with one embodiment of the present invention;

FIG. 3 is a demonstrative illustration of a simplified structure of a solar cell in accordance with another embodiment of the present invention;

FIG. 4 is a simplified flowchart illustration of a method of forming the solar cell illustrated in FIG. 3 in accordance with another embodiment of the present invention; and

FIG. 5 is a demonstrative illustration of a simplified structure of a solar cell in accordance with yet another embodiment of the present invention.

It will be appreciated that for the purpose of simplicity and clarity of illustration, elements in the drawings have not necessarily been drawn to scale. For example, dimensions of some of the elements may be exaggerated relative to other elements for clarity purpose.

### DETAILED DESCRIPTION OF THE INVENTION

In the following detailed description, numerous specific details are set forth in order to provide a thorough understanding of embodiments of the invention. However, it will be understood by those of ordinary skill in the art that embodiments of the invention may be practiced without these specific details. In the interest of not obscuring presentation of essences and/or embodiments of the present invention, in the following detailed description, processing steps and/or operations that are well known in the art may have been combined together for presentation and/or for illustration purpose and in some instances may not have been described in detail. In other instances, processing steps and/or operations that are well known in the art may not be described at all. A person skilled in the art will appreciate that the following descriptions have rather focused on distinctive features and/or elements of embodiments of the present invention.

In the following detailed description, well-known device processing techniques and/or steps may not be described in detail and, in some instances, may be referred to other published articles or patent applications in order not to obscure the description of the essence of presented invention as further detailed herein below.

One embodiment of the present invention provides a silicon-based solar cell or solar energy converter with enhanced optical absorption performance over a larger range than a conventional silicon solar cell. By the use of a porous silicon (a first semiconductor material) in which the pores contain quantum dots of a second semiconductor material with a smaller band-gap than that of silicon, the lower energy (longer wavelength) portions of the sunlight spectrum, that would otherwise not contribute to photocurrent in a conventional silicon solar cell, are absorbed and therefore contribute to the efficiency of the porous silicon solar cell.

Another embodiment of the present invention provides a silicon-based solar cell, or solar energy converter or converting device, with enhanced efficiency by using porous silicon in which the pores are filled substantially with, for example by a chemical vapor deposition process, a second semiconductor material having a lower band-gap than silicon. The second semiconductor absorbs light, more specifically sunlight, of longer wavelength and contributes photocurrent beyond the wavelength range of a conventional silicon solar cell. When the size of pores is made in a quantum range of, for example, approximately less than 10 nm, such second semiconductor material acts similarly to quantum dots as described above except that it is in intimate contact with walls of the pores of a first semiconductor material. Such pores of approximately less than 10 nm in size, filled with the second semiconductor material, may be referred to hereinafter as “quantum volume” in analogy with quantum dots.

Yet another embodiment of the present invention provides an energy converter or energy converting device that makes use of a porous silicon region in which the pores are filled with a mixture of an electrolyte and quantum dots. The energy converting device may be known as an electrochemical device in which the silicon and quantum dots together absorb sunlight to create hole-electron pairs. The electrons are then conducted through the silicon to an electrode while the holes are conducted by the electrolyte within the pores to an opposite electrode. Various embodiments of the present invention, as briefly mentioned above, are described below in more details.

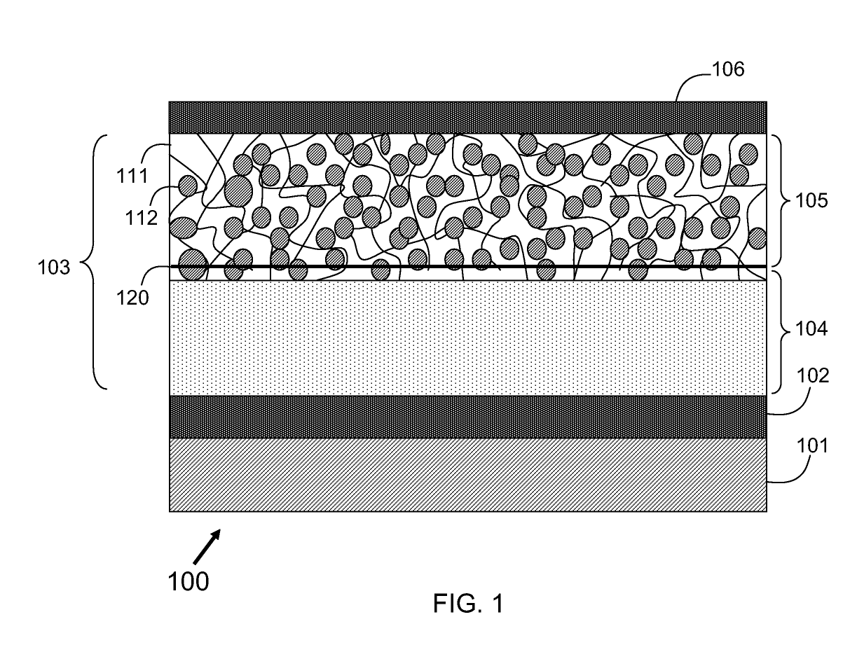

Reference is now made to FIG. 1, which is a demonstrative illustration of a simplified structure of a solar cell in accordance with one embodiment of the present invention. Solar cell 100 may be known as an energy converter or solar energy converter and, according to one embodiment, may be a solid solar cell. Solar cell 100 may include a substrate 101, which may be made of a low cost substrate such as, for example, glass, ceramic, metal, plastic, or semiconductor materials; an electrode or electrode layer 102 (a first electrode) on top of substrate 101; a region or a layer of silicon material 103 on top of electrode layer 102; and an electrode or electrode layer 106 (a second electrode) on top of silicon layer 103. Substrate 101 may include materials that are not necessarily “low cost” materials.

Silicon layer 103 may be a bulk silicon wafer or a thin film of silicon material, and may include at least an upper region 105 and a lower region 104. Upper region 105 may include a first conductivity type, for example a p-doped type, silicon material and lower region 104, or the remainder region, may include a second conductivity type, which may be an opposite conductivity type such as an n-doped type, silicon material. At an interface 120 between upper region 105 of the first conductivity type and lower region 104 of the second conductivity type, a P-N junction may be formed.

According to embodiments of the present invention, upper region 105 and at least a portion of lower region 104, or upper region 105, or at least a portion of upper region 105 may be made porous or being a porous silicon 111. The P-N junction described above may thus be formed either in the porous silicon region, or in the non-porous silicon region, or at an interface between the porous and non-porous regions. FIG. 1 illustrates that P-N junction 120 is formed in the porous region 111 of silicon layer 103. The region of porous silicon 111 may be embedded or dispersed with quantum dots 112 of one or more semiconductor materials, which are typically different from silicon. The one or more semiconductor materials making quantum dots 112 may include materials having a band-gap smaller than that of silicon. Such semiconductor materials may include, for example, Ge, GaSb, PbSe, PbS, InAs, InSb, PbTe, and/or GaInAs. The size of quantum dots 112 are typically less than 10 nm, preferably in a range between approximately 1˜7 nm, and more preferably in a range between about 2˜5 nm. According to one embodiment, the use of quantum dots 112 of semiconductor materials having a smaller band-gap may extend response range of solar cell 100 to longer wavelengths, where silicon by itself usually does not, or at least not efficiently, absorb light or solar rays, thus increasing the overall efficiency of solar cell 100.

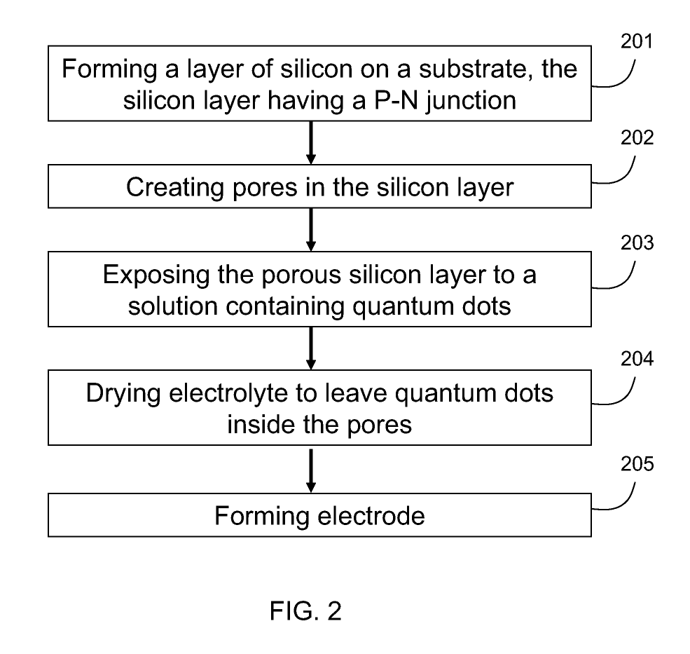

Reference is now made to FIG. 2, which is a simplified flowchart illustration of a method of forming the solar cell illustrated in FIG. 1 in accordance with one embodiment of the present invention. Embodiments of the method may include first forming an electrode (102) on top of a substrate (101). Then at block 201, the method forms a layer of silicon (103) on the substrate (101) via the electrode (102). The silicon layer (103) may include two regions of different conductivity types which create a P-N junction at their interface. Next, at block 202, at least a portion of the silicon layer (103), for example, the upper region (105) and a portion of the lower region (104), may be made porous by means known in the art. For example, pores may be created inside silicon layer 103 by a voltage-assisted etching process in a solution containing hydrofluoric acid (HF). Pores of different sizes and geometries, in a wide range as may be desired, may be obtained by adjusting the chemical composition of HF acid in the chemical etching bath and controlling the amount of voltage and/or current that is applied during porous region formation. The depth of the porous Si region may be controlled by the length of time used in creating the pores.

At block 203, embodiments of the method may include exposing the porous region of silicon layer 103 to a solution containing a density of quantum dots, such that after a pre-determined time elapses, the pores may become saturated with the quantum dots. At block 204, embodiments of the method may include drying the solution, thereby leaving the quantum dots residing in the pores of silicon layer 103. Embodiments of the method may further include, at block 205, forming an electrode (106) on top of the porous silicon layer (103). The types of electrodes that may be used may include, for example, a metal grid in the surface region that is sufficiently conducting, or a transparent conducting oxide (TCO) such as Tin oxide (SnO), Indium oxide (InO), zinc oxide (ZnO), and the like.

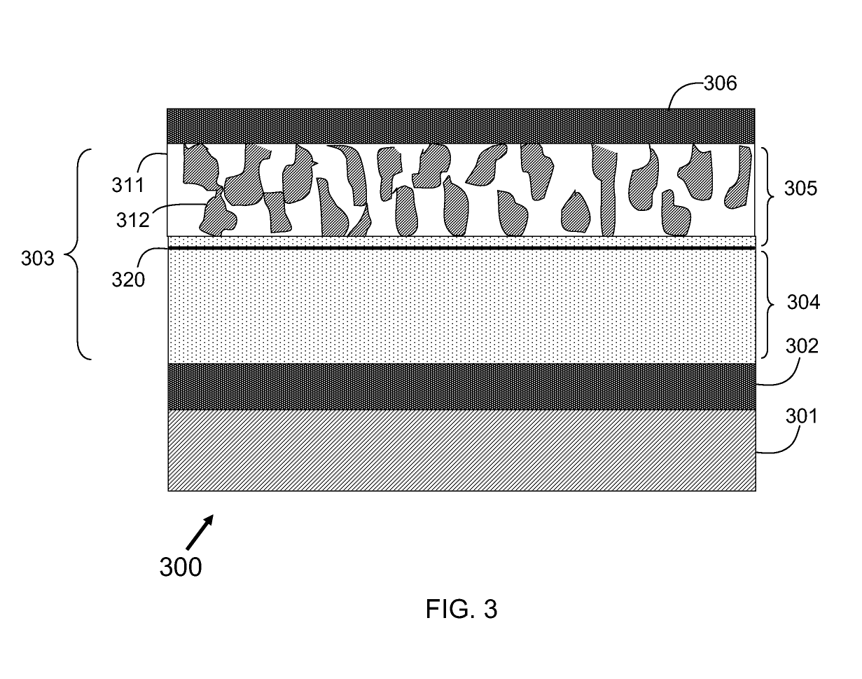

Reference is now made to FIG. 3, which is a demonstrative illustration of a simplified structure of a solar cell in accordance with another embodiment of the present invention. Similar to FIG. 1, solar cell or solar energy converter 300 may include a substrate 301, which may be made of a low cost, although may not be necessarily, substrate such as, for example, glass, ceramic, metal, plastic, or semiconductor materials; an electrode or electrode layer 302 (a first electrode) on top of substrate 301; a region or a layer of silicon material 303 on top of electrode layer 302; and an electrode or electrode layer 306 (a second electrode) on top of silicon layer 303. In addition, silicon layer 303 may include an upper region 305 and a lower region 304. Upper region 305 may include a first conductivity type, and lower region 304 may include a second conductivity type, of silicon material. At an interface between upper region 305 and lower region 304, a P-N junction 320 may be formed.

At least a portion of silicon layer 303, for example a portion of upper region 305, may be porous silicon 311 or may be made porous. The size and geometry of pores 312 may vary in a wide range from large (around a fraction of a micron) to small (around a few nm). In one embodiment of the invention, pores 312 of the porous silicon region 305 may have the size of a quantum dot, which is less than approximately 10 nm, and may be filled substantially with a semiconductor material such as, for example, Ge, PbS, PbSe, PbTe, InAs, InSb, GaSb, and GaInAs, that has a band-gap smaller than that of silicon. Here, it is noteworthy that a person skilled in the art will appreciate that one or more suitable semiconductor materials may fill the pores 312. Semiconductor materials filled in pores 312 are in intimate or substantially intimate contact with walls of pores 312, which enhances charge transfer between the semiconductor materials and the silicon, enabling photovoltaic action. In FIG. 3, P-N junction 320 is illustrated as being located in the non-porous region of silicon layer 303. However, the present invention may not be limited in this respect and P-N junction 320 may be located in porous region 311, or at the interface between the two regions.

Large pores filled with semiconductor materials of band-gap smaller than silicon may enhance light absorption performance of solar cell 300, particularly at longer wavelength since semiconductor materials in the pores generally absorb light better at these wavelengths. The pores may then transfer photon-induced or photon-generated electronic charges to surrounding silicon material for photocurrent collection and photovoltaic action. When the size of the pores becomes less than 10 nm, for example becomes between about 1-7 nm or preferably between about 2-5 nm, the pores filled with above semiconductor materials effectively become quantum dots, which may be referred to hereinafter as “quantum volume” 312 in analogy to quantum dots 112 of FIG.1. Quantum volume 312 may demonstrate enhanced performance of light absorption properties similar to those of quantum dots while exhibiting other added benefit of intimate or substantially intimate contact with the pore walls.

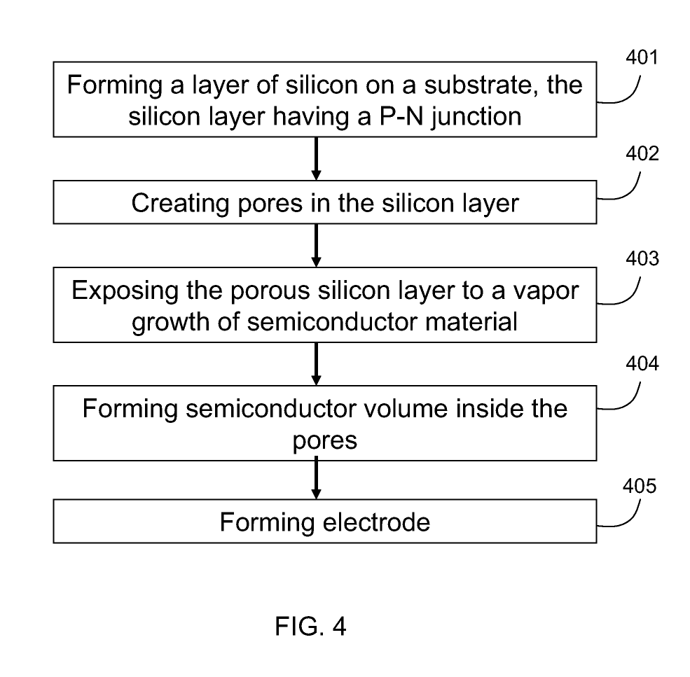

Reference is now made to FIG. 4, which is a simplified flowchart illustration of a method of forming the solar cell illustrated in FIG. 3 in accordance with another embodiment of the present invention. Similar to method steps being cited in blocks 201 and 202 in FIG. 2, embodiments of the present method may include forming a silicon layer (303) on a substrate (301), via a pre-formed first electrode (302), at block 401, and creating pores (312) in the silicon layer (303) at block 402. Next at block 403, embodiments of the method may include exposing the porous silicon layer to a vapor growth condition or environment of a semiconductor material or semiconductor materials which has a band-gap smaller than that of silicon, and causing the formation of semiconductor volumes inside the pores (312) at block 404. After the pores have been filled, or substantially filled with the semiconductor material(s), in other words, the semiconductor becomes substantially in intimate contact with walls of the pores, a second electrode (306) may be applied on top of the silicon layer (303). Size of the pores (312) may vary, and for those with a size less than approximately 10 nm, the semiconductor filled pores may become quantum volumes analogous to quantum dots.

In the above embodiments, semiconductor materials are used in forming quantum dots (as in FIG. 1 and FIG. 2) or quantum volume (as in FIG. 3 and FIG. 4). Embodiments of the present invention, however, are not limited in this respect. For example, materials other than semiconductor material such as metals may also be used in forming quantum dots and/or quantum volume in the porous region of silicon layer 103 or 303. Generally, under normal circumstances, metals are not used as active light-absorbing element in a solar cell. However, at dimensions being as small as the quantum range (less than 10 nm), photon-generated carriers in metals may actually exit the metal and be released into surrounding silicon in times shorter than a recombination time in the metal. Therefore, metals may be suitable for making quantum dots and/or quantum volume according to some embodiments of the invention.

According to yet another embodiment of the present invention, structures of FIG. 1 or FIG. 3 may also be used for light emission application when the semiconductor material used in forming the quantum dot/quantum volume in the pores is chosen to have a higher band-gap than that of silicon. Porous silicon contained between suitable electrodes may emit light in a visible wavelength region when a bias is applied across the structure. Materials such as, for example, CdS, ZnS, ZnSe, CdSe, CdTe, GaN, InN, ZnTe, InP, GaP, and GaAs, have larger band-gap than that of silicon and may significantly contribute to the light emission.

In case metal particles are used in forming quantum dots or quantum volumes, they may also enhance the light output because they focus the electric field more strongly into the pores than without such metal. Metal particles such as silver, nickel, for example, are known to have this field-enhance effect because their dielectric constant is much higher than the silicon. High electric fields create light emission by electroluminescence, whereby charge carriers are accelerated by the electric field until enough energy is gained to recombine with the emission of light.

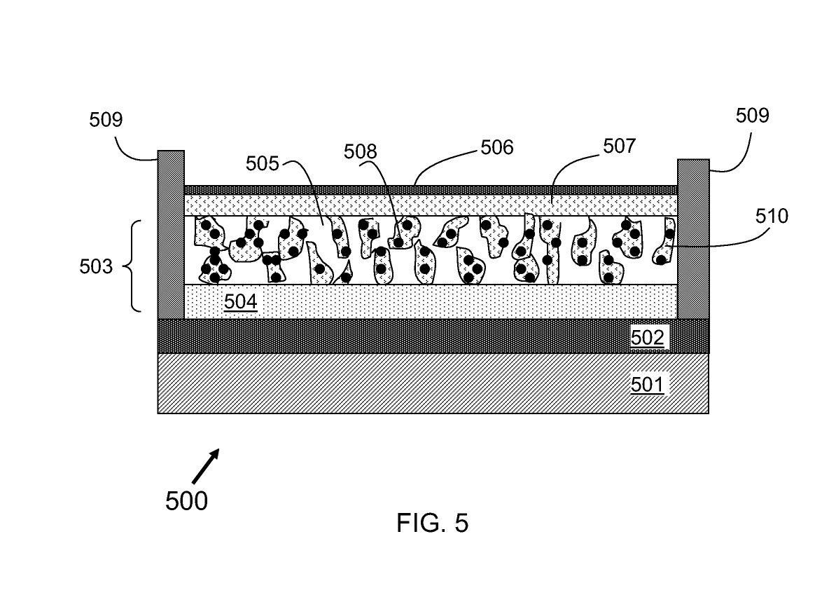

Reference is now made to FIG. 5, which is a demonstrative illustration of a solar cell according to yet another embodiment of the present invention. Solar cell or solar energy converter 500 may include a substrate 501, which may be made of a low cost substrate such as, for example, glass, ceramic, metal, plastic, or semiconductor; an electrode or electrode layer 502 (a first electrode) on top of substrate 501; a region or a layer of silicon material 503 on top of electrode layer 502; and a transparent conduct oxide (TCO) layer 506 (a second electrode) on top of silicon layer 503.

Similar to solar cell 100 and 300 in FIG. 1 and FIG. 3, silicon layer 503 may be a bulk silicon wafer or a thin film of silicon material. At least a portion of layer 503, such as region 505, may be made porous by means known in the art, such as described herein above, and may reside on a non-porous region 504. The thickness of non-porous region 504 may be less than the thickness of porous region 505. Alternatively, the entire region of Si layer 503 may be made porous.

According to embodiments of the present invention, pores 510 in the porous silicon region 505 may be dispersed with quantum dots 508 which are immersed in an electrolyte solution 507 being contained by sidewall 509, as is illustrated in FIG. 5. Solar cell 500 may therefore be referred to as an electrochemical cell hereinafter. Electrolyte solution 507 within sidewall 509 may fill the pores 510 of porous region 505, and according to one embodiment may cover a top surface of porous region 505 of silicon layer 503.

Electrolyte 507 may also contains a redox chemical such that electrons, induced or generated by light absorption either in the silicon region 503 or by quantum dots 508, may travel to electrode 502 while the holes created at the same time may react with the redox chemical in the electrolyte so that in effect the holes are transported to upper electrode 506. Electrochemical cell 500 differs from solid solar cells 100 in that, in solar cell 100 the solution used to deposit or spread quantum dots into the pores in solar cell 100 need not be an electrolyte and is dried after deposition, while in electrochemical cell 500 the solution is an electrolyte or gel which is not dried after the device is formed.

When being compared with a conventional electrochemical cell normally made with dye-coated TiO₂ particles encased in a liquid electrolyte or gel electrolyte, electrochemical solar cell 500 includes a porous silicon layer that contains quantum dots 508 that may absorb light or solar rays much more efficiently than dye/TiO₂ cell in a conventional electrochemical cell. The quantum dots 508, being made of a semiconductor material different from silicon, extend the wavelength response of electrochemical solar cell 500 into at least the infrared region and thereby increase the overall current output of solar cell 500. Electrochemical solar cell 500 and the forming of quantum dots in silicon layer 503 may be made in similar steps as those described above with regard to solar cell 100, and illustrated in FIG. 2.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the spirit of the invention.

What is claimed is:

1. An energy converter, comprising:
a silicon layer having at least two regions of a first and a second conductivity type that form a P-N junction, at least a portion of said silicon layer being porous, and pores in said portion of porous silicon containing a semiconductor material, said semiconductor material being different from silicon; and
a first and a second electrode being placed at a bottom and a top surface of said silicon layer respectively.

2. The energy converter of claim 1, wherein said semiconductor material comprises quantum dots, said quantum dots having a size less than 10 nm and being dispersed in said pores.

3. The energy converter of claim 2, wherein said quantum dots have a size between about 1 nm and about 7 nm, and preferably between about 2 nm and about 5 nm.

4. The energy converter of claim 1, wherein said semiconductor material has a band-gap smaller than that of silicon, and is selected from a group consisting of InAs, InSb, GaSb, PbS, PbSe, PbTe, Ge, and GaInAs.

5. The energy converter of claim 1, wherein at least one of said first and second electrodes is a metal grid or a transparent conducting oxide of tin oxide (SnO), zinc oxide (ZnO) or indium oxide (InO).

6. The energy converter of claim 1, wherein said silicon layer is a thin-film of silicon or a bulk silicon wafer being formed on top of a substrate via said first electrode.

7. The energy converter of claim 6, wherein said substrate is selected from a group consisting of glass, ceramic, plastic, metal, and semiconductor.

8. The energy converter of claim 1, wherein said pores in said portion of porous silicon have a size less than 10 nm, and are substantially filled with said semiconductor material, which is in substantially intimate contact with walls of said pores.

9. The energy converter of claim 8, wherein said pores are quantum volume, said quantum volume having a size between about 1 nm and about 7 nm, and preferably between about 2 nm and about 5 nm.

10. The energy converter of claim 1, wherein said semiconductor material has a band-gap larger than that of silicon, and is selected from a group consisting of CdSe, CdS, CdTe, ZnSe, ZnTe, ZnS, GaN, InN, GaAs, GaP, and InP.

11. The energy converter of claim 1, wherein said first conductivity type silicon is a p-doped type silicon and said second conductivity type silicon is an n-doped type silicon.

12. An energy converting device comprising:
a first region of non-porous silicon;
a second region of porous silicon on top of, and in contact with, said first region, said second region comprising pores, said pores containing therein a semiconductor material, said semiconductor material being different from silicon;
a bottom electrode contacting said non-porous silicon region; and
a top electrode contacting said porous silicon region.

13. The energy converting device of claim 12, further comprises an electrolyte covering a top surface of said porous silicon of said second region, wherein said pores of said porous silicon being filled with said electrolyte.

14. The energy converting device of claim 13, wherein said semiconductor material comprises quantum dots, said quantum dots being immersed in said electrolyte inside said pores of said porous silicon of said second region.

15. The energy converting device of claim 14, wherein said quantum dots have a size between about 1 nm and about 7 nm, and preferably between about 2 nm and about 5 nm.

16. A solar cell comprising:
a substrate;
a first electrode on top of said substrate;
a silicon layer having a non-porous region and a porous region, said non-porous region being on top of said first electrode, pores in said porous region being saturated with a semiconductor material, said semiconductor material being different from silicon;
a P-N junction formed at an interface between a p-type conductivity region and an n-type conductivity region of said silicon layer; and
a second electrode on top of said porous region of said silicon layer.

17. The solar cell of claim 16, wherein said semiconductor material has a band-gap smaller than that of silicon, and is selected from a group consisting of InAs, InSb, GaSb, PbS, PbSe, PbTe, Ge, and GaInAs.

18. The solar cell of claim 16, wherein said pores in said porous region have a size less than approximately 10 nm, and preferably between 2 nm and 5 nm.

19. The solar cell of claim 16, wherein said P-N junction is located in said non-porous region of said silicon layer.

20. A method of manufacturing an energy converter, said method comprising:
forming a layer of silicon on a substrate, said substrate having a first electrode thereupon;
creating pores in at least a portion of said layer of silicon, thus forming a porous silicon region of said layer of silicon;
filling said pores in said porous silicon region with a semiconductor material different from silicon; and
forming a second electrode on top of said layer of silicon.

21. The method of claim 20, wherein creating pores in said portion of said layer of silicon comprises controlling process conditions to form said pores that have a size in dimension less than approximately 10 nm, between about 1 nm and about 7 nm, and preferably between about 2 nm and about 5 nm.

22. The method of claim 20, wherein said layer of silicon has first and second conductivity types which form a P-N junction, and wherein filling said pores in said porous silicon region comprises:
exposing said porous silicon region to a solution containing quantum dots of said semiconductor material; and
drying electrolyte of said solution and leaving said quantum dots inside said pores.

23. The method of claim 20, wherein said layer of silicon has first and second conductivity types which form a P-N junction, and wherein filling said pores in said porous silicon region comprises:
exposing said porous silicon region to a vapor growth condition of said semiconductor material; and
causing said semiconductor material to fill said pores and in substantially intimate contact with walls of said pores in said porous silicon region of said layer of silicon.

24. The method of claim 20, wherein said semiconductor material is quantum dots, further comprising filling said pores with an electrolyte, said electrolyte includes a redox chemical.

25. The method of claim 20, wherein filling said pores in said porous silicon region with a semiconductor material comprises applying said semiconductor material with a band-gap smaller than silicon, said semiconductor material is selected from a group consisting of InAs, InSb, GaSb, PbS, PbSe, PbTe, Ge, and GaInAs.
